(19) United States
(12) Patent Application Publication
(10) Pub. No.: US 2002/0140059 A1
(43) Pub. Date: Oct. 3, 2002

(54) Semiconductor device

(76) Inventors: Misuk Yamazaki, Kashiwa (JP); Makoto Kitano, Tsuchiura (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/066,591

(22) Filed: Feb. 6, 2002

(30) Foreign Application Priority Data
Mar. 29, 2001 (JP) 2001-94553
Dec. 27, 2001 (JP) 2001-395633

(51) Int. Cl. H01L 29/861

(52) U.S. Cl. 257/658; 257/683

(57) ABSTRACT

A semiconductor device includes a lead electrode connected to a lead, a case electrode having a projection part around its periphery, and a semiconductor chip having a rectification function and connected electrically between the lead electrode and the case electrode through connection members, wherein an electrically conductive plate is provided between the semiconductor chip and the lead electrode. Thereby, any of cracks is prevented from being generated in the semiconductor chip due to the mutual thermal deformation difference between the electrically conductive plate and the semiconductor chip which are electrically joined to each other through a joining member.

### BACKGROUND OF THE INVENTION

1. Field of the Invention

The present invention relates to a semiconductor device for converting an A.C. output signal from an A.C. generator into a D.C. output signal. More particularly, the invention relates to a rectifier, for use in an A.C. generator for vehicles or the like, which is used under the hard environment in which the thermal shock is repeatedly applied thereto with a large number of times.

2. Description of the Related Art

As for a general alternator for vehicles, a plastic encapsulated diode incorporated with a semiconductor chip as an element for rectifying an output signal from an alternator in flexible resin is disclosed in JP-A-7-161877.

In addition, in JP-A-7-221235, there is disclosure of a structure that an electrically conductive plate having a three-layered structure of a copper-iron alloy-copper is intervened between a case electrode and a semiconductor chip in order to produce a diode, the electrical characteristics of which are not degraded for a long term even under the hard environment with the thermal shock repeatedly applied a number of times. This structure is used for absorbing the mechanical stress exerted to the semiconductor chip and preventing cracks from being generated in the semiconductor chip by setting the linear expansion coefficient of the electrically conductive plate to all intermediate in the linear expansion coefficient between the case electrode and the semiconductor chip.

In addition, in JP-A-5-191956, there is described a diode in which a lead, a semiconductor chip, an electrically conductive plate and a case electrode are laminated in this order from the lead side, and a space defined between the case electrode, and the semiconductor chip and the like is filled with an insulating member. The semiconductor chip of this diode has the reverse breakdown characteristics and the junction part thereof has the mesa structure of the diffusion type employing P type silicon.

With this mesa structure, the relatively large electric surge breakdown voltage in the reverse direction can be obtained, and also the reverse recovery time can be reduced. In addition, the forward voltage drop can also be reduced and hence the loss in the essential rectification can be reduced.

In JP-A-5-191956 described above, there is shown the structure in which the electrically conductive plate made of copper-invar-copper (CIC) for absorbing the thermal stress due to the differential thermal expansion between the case electrode and the semiconductor chip is made lie between the case electrode and the semiconductor chip. That is, the coefficient of linear expansion of the electrically conductive plate is set to an intermediate value in the coefficient of linear expansion between the case electrode and the semiconductor chip, whereby the thermal stress applied to the semiconductor chip is reduced. However, since the electrically conductive plate is provided between the semiconductor chip and the case electrode, the calorification of the semiconductor chip is difficult to be radiated to the case electrode fixed to the heat radiating plate. For this reason, there is the possibility that the temperature of the semiconductor chip may rise.

### SUMMARY OF THE INVENTION

In the light of the foregoing, the present invention has been made in order to solve the above-mentioned problem, and it is therefore an object of the present invention to provide a semiconductor device in which any of cracks in a semiconductor chip due to the mutual thermal deformation difference between a case electrode and a semiconductor chip which are electrically joined to each other by a joining member is prevented from being generated, and also the heat radiating property of the semiconductor chip is enhanced.

In order to attain the above-mentioned object, according to the present invention, it is preferable that an electrically conductive plate is provided on the side of a lead electrode of a semiconductor chip and also no electrically conductive plate is provided on the side of a case electrode.

(1) According to an aspect of the present invention, there is provided a semiconductor device having a lead electrode connected to a lead, a case electrode having a projection part around its periphery, and a semiconductor chip having a rectification function and connected electrically between the lead electrode and the case electrode through connection members, wherein an electrically conductive plate is provided between the semiconductor chip and the lead electrode. As a result, the generation of any of cracks in the semiconductor chip due to the mutual thermal deformation difference between the electrically conductive plate and the semiconductor chip which are electrically joined to each other through a joining member can be prevented, the heat radiating property of the semiconductor chip can be enhanced and also the reverse surge breakdown voltage can be increased.

To put it concretely, no electrically conductive plate is provided between the semiconductor chip and the case electrode fixed to radiation fins, but the semiconductor chip and the case electrode are electrically connected to each other through a joining member. Therefore, the excellent heat radiating property can be obtained and hence the reverse surge breakdown voltage can be increased.

In addition, since the electrically conductive plate is provided on the side opposite to the case electrode, it is possible to reduce the influence exerted on the semiconductor chip by the differential thermal expansion among the case electrode, the lead electrode and the semiconductor chip and also it is possible to reduce the damage, such as the generation of cracks, exerted to the semiconductor chip.

(2) There is provided a semiconductor device according to the item (1), wherein the coefficient of linear expansion of the electrically conductive plate is smaller than that of the case electrode and also is equal to or larger than 50% of that of the semiconductor chip. Normally, each of the lead electrode and the case electrode is made of copper-based or iron-based metal. In the case where each of those electrodes is made of copper-based metal for example, its coefficient of linear expansion is about 17 ppm/° C., while the coefficient of linear expansion of the semiconductor chip is 3 ppm/° C. Then, the electrically conductive plate provided between the semiconductor chip and the lead electrode is made of metal having the coefficient of linear expansion which is smaller than that of the case electrode, but is equal to or larger than 50% of that of the semiconductor chip, i.e., equal to or larger than 1.5 ppm/° C. but equal to or smaller than 17 ppm/° C. As a result, even if the thermal shock is repeatedly exerted to the semiconductor chip a large number of times, since the difference in thermal expansion between the electrically conductive plate and the semiconductor chip is small, it is possible to reduce the deformation of the semiconductor chip due to the difference in coefficient of linear expansion between the semiconductor chip which is electrically connected to the electrically conductive plate through a connection member and the case electrode, and hence it is possible to reduce the stress generated in the semiconductor chip.

(3) There is provided a semiconductor according to the item (1), wherein the strength of the electrically conductive plate is larger than that of the case electrode. In this case, for example, the constituent of the case electrode is either copper or copper containing zircon. Normally, since the elastic modulus of copper-based metal is 120 GPa, the material having the elastic modules equal to or larger than 120 GPa is employed for the electrically conductive plate. As for a method of fixing the case electrode to radiation fins, there are a type of fixing the case electrode to radiation fins through a joining member and a type of pressingly fitting the case electrode to a hole of the radiation fins to fix it thereto. In the case of the type of pressingly fitting the case electrode to a hole of the radiation fins to fix it thereto, the case electrode are deformed, which results in that the semiconductor chip is also deformed by that deformation. According to the present invention, it is possible to reduce the influence exerted on that deformation.

(4) There is provided a semiconductor device according to the item (1), wherein the constituent of the case electrode has the layer structure of a copper-iron alloy-copper. In addition, it is preferable that the above-mentioned iron alloy has the composition of a 30% to 50% Ni-remainder Fe or a 20% to 40% Ni-50% to 60% Fe-remainder Co. Also, for example, the iron alloy of a three-layered structure having the copper-iron alloy-copper has a thickness in the range of 1.5 to 8 times as large as that of each of the copper layers. For example, in the case where the iron alloy of copper-iron alloy-copper is invar and the thickness ratio of the three layers is 1:3:1, the coefficient of linear expansion of the case electrode is 6.9 ppm/° C., while in the case where the iron alloy is coval and the thickness ratio thereof is 1:3:1, the coefficient of linear expansion thereof is 6.0 ppm/° C. This means that the three-layered structure of copper-iron alloy-copper has both of the low thermal expansion characteristics and the high heat conduction characteristics is employed as the material of the case electrode, whereby it is possible to reduce the deformation of the semiconductor chip due to the difference in coefficient of linear expansion between the semiconductor chip and the case electrode.

(5) There is provided a semiconductor device according to the item (1), wherein the electrically conductive plate has the layer structure of copper-iron alloy-copper. Then, it is preferable that the iron alloy has the composition of the 30% to 50% with Ni remainder Fe or the 20% to 40% Ni-50% to 60% with Fe remainder Co. In the same manner as that in the item (4), it is possible to reduce the deformation of the semiconductor chip due to the difference in coefficient of linear expansion between the electrically conductive plate and the semiconductor chip.

(6) There is provided a semiconductor device according to the item (1), wherein the electrically conductive plate is made of a metal material having the composition of the 30% to 50% with Ni remainder Fe or the 20% to 40% Ni-50% to 60% with Fe remainder Co. For example, the electrically conductive plate may be made of invar (alloy of 35% Ni—Fe). In addition, it is preferable that a thickness of the electrically conductive plate is equal to or larger than 50% of that of the semiconductor chip. This means that the coefficient of linear expansion of invar is 1.5 ppm/° C., whereas the coefficient of linear expansion of the semiconductor chip is 3 ppm/° C. which is larger than that of invar. A thickness of the electrically conductive thickness is made larger than that of the semiconductor chip, whereby it is possible to reduce the difference in thermal expansion between the electrically conductive plate and the semiconductor chip. In addition, since the thickness of the electrically conductive plate is increased, whereby the function of reducing the deformation of the semiconductor chip is also enhanced, it can be expected that the stress exerted to the semiconductor chip is reduced.

(7) There is provided a semiconductor device according to the item (1), wherein the electrically conductive plate is a conductive plate in which Mo is the main constituent element, and has a thickness equal to or larger than 100% of that of the semiconductor chip.

This means that since the efficient of linear expansion of molybdenum is 5.1 ppm/° C., the thickness of the electrically conductive plate is made smaller than that of the semiconductor chip, whereby it is possible to reduce the difference in thermal expansion between the electrically conductive plate and the semiconductor chip. The electrically conductive plate, for example, may be a conductive plate in which Mo is the main constituent element, and also may have a thickness equal to or lower than 200% of that of the semiconductor chip.

(8) There is provided a semiconductor device according to the item (1), wherein the electrically conductive plate is a conductive plate in which W is the main constituent element, and has a thickness equal to or larger than 100% of that of the semiconductor chip.

This means that since the coefficient of linear expansion of tungsten is 4.5 ppm/° C., the thickness of the electrically conductive plate is made smaller than that of the semiconductor chip, whereby it is possible to reduce the difference in thermal expansion between the electrically conductive plate and the semiconductor chip. Then, it is preferable that the electrically conductive plate is a conductive plate in which W is the main constituent element, and has a thickness equal to or smaller than 200% of that of the semiconductor chip.

(9) According to another aspect of the present invention, there is provided a semiconductor device having a lead electrode connected to a lead, a case electrode having a projection part around its periphery, and a semiconductor chip having a rectification function and connected electrically between the lead electrode and the case electrode through connection members, wherein an electrically conductive plate is provided between the semiconductor chip and the lead electrode, and the electrically conductive plate is formed in such a way that its width is equal to or smaller than 90%, but is equal to or larger than 50% of that of the semiconductor chip. This means that in the case where the electrically conductive plate having the larger coefficient of linear expansion than that of the semiconductor chip is provided, the width of the electrically conductive plate is reduced, whereby it is possible to reduce the difference in thermal expansion between the electrically conductive plate and the semiconductor chip.

(10) According to still another aspect of the present invention, there is provided a semiconductor device having a lead electrode connected to a lead, a case electrode having a projection part around its periphery, and a semiconductor chip having a rectification function and connected electrically between the lead electrode and the case electrode through solder, wherein an electrically conductive plate is provided between the semiconductor chip and the lead electrode, but no electrically conductive plate is provided between the semiconductor chip and the case electrode, and the lead electrode and the electrically conductive plate are formed in such a way that a width of each of them is smaller than that of the semiconductor chip, and the solder between the semiconductor chip and the electrically conductive plate is formed in such a way that its width of the side end of the semiconductor chip is smaller than that of the side end of the electrically conductive plate.

As a result, it is possible to prevent the generation of the strain concentrating on the end part of the solder, through which the electrically conductive plate and the semiconductor device are electrically joined to each other, due to the shape of the end part of the solder.

In addition, to put it concretely, according to yet another aspect of the present invention, there is provided a semiconductor device having a lead electrode connected to a lead, a case electrode having a projection part around its periphery, and a semiconductor chip having a rectification function and connected electrically between the lead electrode and the case electrode through solder, wherein an electrically conductive plate is provided between the semiconductor chip and the lead terminal, but no electrically conductive plate is provided between the semiconductor chip and the case electrode, and the lead electrode and the electrically conductive plate are formed in such a way that a width of each of them is smaller than that of the semiconductor chip, and the solder between the semiconductor chip and the electrically conductive plate is formed in such a way that its width of the side end of the electrically conductive plate is smaller than that of the side end of the semiconductor chip, and the solder between the semiconductor chip and the case electrode is formed in such a way that its width of the side end of the semiconductor chip is smaller than that of the side end of the case electrode.

### BRIEF DESCRIPTION OF THE DRAWINGS

FIG. 1 is a vertical cross sectional view showing the structure of a semiconductor device, according to an embodiment of the present invention, which is applied to a rectification diode of an A.C. generator for vehicles;

FIG. 2 is a vertical cross sectional view showing the structure of a semiconductor device, according to another embodiment of the present invention, which is applied to a rectification diode of an A.C. generator for vehicles;

FIG. 3 is a vertical cross sectional view showing the structure of a semiconductor device, according to still another embodiment of the present invention, which is applied to a rectification diode of an A.C. generator for vehicles;

FIG. 4 is a vertical cross sectional view showing the structure of a semiconductor device, according to yet another embodiment of the present invention, which is applied to a rectification diode of an A.C. generator for vehicles;

FIG. 5 is a vertical cross sectional view showing the structure of a semiconductor device, according to a further embodiment of the present invention, which is applied to a rectification diode of an A.C. generator for vehicles;

FIG. 6 is a vertical cross sectional view showing the structure of a semiconductor device, according to an even further embodiment of the present invention, which is applied to a rectification diode of an A.C. generator for vehicles;

FIG. 7 is a graphical representation useful in explaining the characteristics of the embodiments of the present invention;

FIG. 8 is a vertical cross sectional view showing the structure of a semiconductor device, according to another embodiment of the present invention, which is applied to a rectification diode of an A.C. generator for vehicles;

FIG. 9 is a vertical cross sectional view showing the structure of a semiconductor device, according to still another embodiment of the present invention, which is applied to a rectification diode of an A.C. generator for vehicles; and

FIG. 10 is a vertical cross sectional view showing the structure of a diode for comparison.

### DETAILED DESCRIPTION OF THE INVENTION

The embodiments of the present invention will hereinafter be described in detail with reference to the accompanying drawings.

The basic structure of a diode for comparison is shown in FIG. 10.

In FIG. 10, reference numeral 1 designates a lead electrode. This lead electrode 1 serves as a connection part through which the electric power is supplied to a semiconductor chip 2. This semiconductor chip 2 and the lead electrode 1 are electrically connected to each other through a connection member 3a. In addition, the semiconductor chip 2 and an electrically conductive plate (metal plate) 4 are electrically connected to each other through a connection member 3b. Reference numeral 5 designates a metal case serving as an electrode material. This case electrode 5 and the electrically conductive plate 4 are electrically connected to each other through a connection member 3c. Each of those connection members 3a, 3b and 3c is generally made of solder. Reference numeral 6 designates an insulating member which is filled in a space defined between the semiconductor chip 2 and the metal case 5, and is generally made of epoxy-based resin or the like.

In this diode for comparison, the breadth of the semiconductor chip 2 is equal to that of the electrically conductive plate. The breadth of the electrically conductive plate 4 is about 600 μm for example. If the breadth of the semiconductor chip 2 is equal to that of the electrically conductive plate 4 in such a manner, then the coefficient of linear expansion of the electrically conductive plate 4 becomes larger than that of the semiconductor chip 2. As a result, there is possibility that the mechanical stress exerted to the semiconductor chip may increase to generate cracks in the semiconductor chip.

In addition, in the case where as apparent from FIG. 10, the electrically conductive plate 4 is provided in such a way as to underlie the semiconductor chip 2, the electrically conductive plate 4 itself becomes the thermal resistance, and hence there arises the problem that the heat from the semiconductor chip 2 is hardly radiated.

Now, an alternator for converting an A.C. output signal from an A.C. generator into a D.C. output signal performs its part of rectifying a current by a diode self-contained therein, and a semiconductor element is generally incorporated in this diode.

On the other hand, since the mounting place of the alternator for converting an A.C. output signal from a generator into a D.C. output signal is located within an engine room of a vehicle, the alternator is easy to suffer highly the influence of the high temperature, the increase of a calorification amount of a generator due to the change in the electrical load on the vehicle side, and the like. In addition, since in particular, a vehicle is under the hard environment in which it suffers the repetitive cooling and heating over a wide temperature range due to the difference in temperature between summer and winter, the semiconductor device is required which is excellent in the heat radiating property and in the thermal fatigue.

As described above, since the alternator is mounted within the engine room of the vehicle in which the temperature is changed violently, it becomes the important problem that how the semiconductor device is prevented from coming under the thermal influence.

However, in recent years, for engines for vehicles, the requirement of the small and high power engine has been increased. If the engine is required to be small and to be of high power, then the calorification temperature will become high all the more. Therefore, with respect to the alternator mounted within the engine room of the vehicle, though there is the difference in temperature between summer and winter, normally, it is required to provide the alternator which may withstand the temperature range from equal to or higher than 180 degrees to −40 degrees.

In particular, as described in JP-A-5-191956, if the semiconductor chip is mounted in such a way as to overlie the electrode case, and also the electrode plate is mounted in such a way as to overlie the semiconductor chip, since the coefficient of linear expansion of each of the electrodes on the upper and lower sides is larger than that of the semiconductor chip, there is possibility that the stress concentrates on the semiconductor chip and cracks are generated in the part of the semiconductor chip on which the stress concentrates.

In the light of the foregoing, the invention of the present application aims at absorbing the stress concentration on the semiconductor chip by changing slightly an electrode plate to prevent any of cracks from being generated in a semiconductor chip.

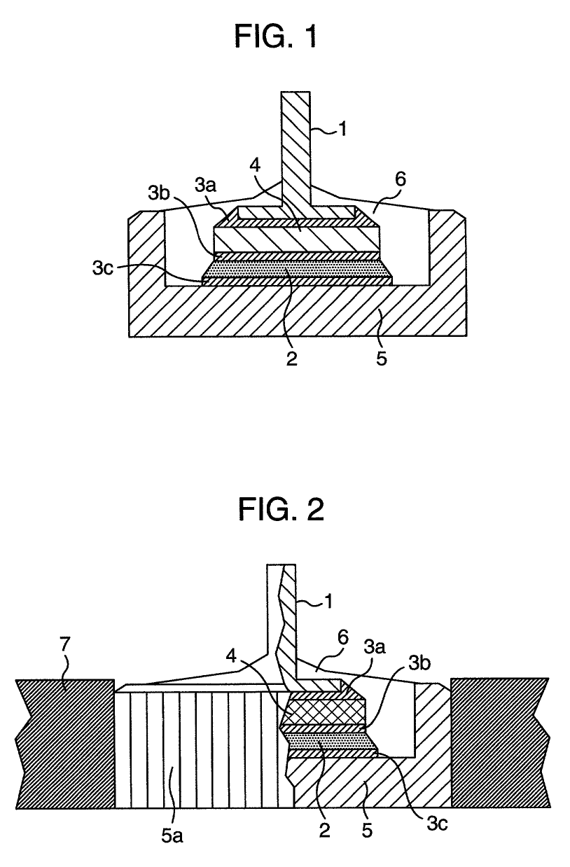

FIG. 1 is a vertical cross sectional view showing the structure of a semiconductor device according to a first embodiment of the present invention.

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through a connection members 3a, 3b, 3c, and also including an insulating member 6, an electrically conductive plate 4 is provided between the semiconductor chip 2 and the lead electrode 1. Then, no electrically conductive plate 4 is provided between the semiconductor chip 2 and the case electrode 5 fixed to radiation fins 7 which are electrically connected to each other through a joining member.

Since no electrically conductive plate 4 is provided between the semiconductor chip 2 and the case electrode 5 fixed to the radiation fins 7 which are electrically connected to each other through the joining member, the high heat radiating property can be obtained and also the reverse surge breakdown voltage can be increased.

In addition, since the electrically conductive plate 4 is provided on the side opposite to the case electrode 5, it is possible to reduce the influence exerted on the semiconductor chip 2 due to the differential thermal expansion between the case electrode 5 and the lead electrode 1, and the semiconductor chip 2, and also it is possible to reduce the damage such as the generation of cracks in the semiconductor chip 2.

While in the above description and the like, there has been stated the example in which no electrically conductive plate 4 is provided between the semiconductor chip 2 and the case electrode 5, if alternatively, an electrically conductive plate 4 is provided between the semiconductor chip 2 and the case electrode 5, then the electrically conductive plate is employed which is thinner than the above-mentioned electrically conductive plate 4.

Describing a semiconductor device according to a second embodiment with reference to FIG. 2, the electrically conductive plate 2 is formed in such a way that its coefficient of linear expansion is smaller than that of the case electrode 5 and also is smaller than that of the semiconductor chip by 50%. Normally, each of the lead electrode 1 and the case electrode 5 is made of copper-based or iron-based metal. In the case where each of those electrodes is made of copper-based metal for example, its coefficient of linear expansion is about 17 ppm/° C., while the coefficient of linear expansion of the semiconductor chip is 3 ppm/° C. In this case, for the electrically conductive plate 4 provided between the semiconductor chip 2 and the lead electrode 5, there is employed metal in which its coefficient of linear expansion is smaller than that of the case electrode 5, but is equal to or larger than 50% of that of the semiconductor chip 2. That is, the electrically conductive plate 4 is made of metal having the coefficient of linear expansion equal to or larger than 1.5 ppm/° C. As a result, even if the thermal shock is repeatedly exerted thereto a large number of times, since the difference in thermal expansion between the electrically conductive plate 4 and the semiconductor chip 2 is small, it is possible to reduce the deformation of the semiconductor chip due to the difference in coefficient of linear expansion between the semiconductor chip and the case electrode which are electrically connected to the electrically conductive plate through a joining member, and also it is possible to reduce the stress generated in the semiconductor chip.

FIG. 2 is a vertical cross sectional view showing the structure of a semiconductor device according to a third embodiment of the present invention.

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through connection members 3a, 3b, 3c, and also including an insulating member 6, an electrically conductive plate 4 is provided between the semiconductor chip 2 and the lead electrode 1, and a constituent component of the case electrode is either copper or copper containing zircon. For example, the strength of the electrically conductive plate 4 is larger than that of the case electrode 5. As for a method of fixing the case electrode 5 to the radiation fins 7, there are a type of fixing the case electrode 5 to the radiation fins 7 through a joining member and a type of fitting pressingly the case electrode 5 to a hole of the radiation fins 7 to fix the case electrode 5 thereto. FIG. 2 shows that an attachment part of the case electrode 5 is a knurling tool 5a fixed to the radiation fins 7 by the press fitting, and the case electrode 5 is pressingly fitted to the radiation fins 7 by the knurling tool 5a to be fixed thereto. While according to this method, the attachment can be carried out with high efficiency by the simple means, the case electrode 5 is deformed during the press fitting, and the semiconductor chip is also deformed by that deformation. For example, when the elastic modulus of the case electrode is 120 GPa, the electrically conductive plate 5 having the strength of equal to or larger than 120 GPa is employed. The trenches formed in the case electrode 5 can increase the surface area of the metal case to enhance the heat radiating efficiency. In addition, the trenches become the press fitting means when inserting the case electrode 5 into the hole. The electrically conductive plate is subject to the stress to be exerted to the semiconductor chip in such a way and the partial stress concentration on the semiconductor chip is absorbed, whereby it is possible to reduce the generation of any of cracks in the semiconductor chip. The generation of any of cracks in the adhesive member such as solder between the semiconductor chip and the case electrode due to the difference in coefficient of linear expansion between the case electrode and the solder chip can be reduced by the electrically conductive plate which is located on the opposite side through the semiconductor chip.

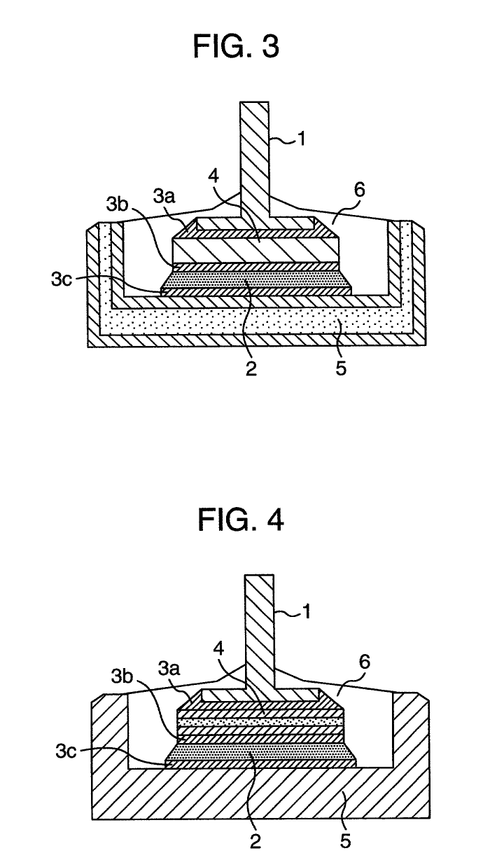

FIG. 3 is a vertical cross sectional view showing the structure of a semiconductor device according to a fourth embodiment of the present invention.

In the figure, in the encapsulation structure having a lead electrode 1 connected to a lead, a case electrode 5 having a projection part around its periphery, and a semiconductor chip having a rectification function and connected electrically between the lead electrode 1 and the case electrode 5 through a connection members 3a, 3b, 3c, and also including an insulating member 6, an electrically conductive plate 4 is provided between the semiconductor chip 2 and the lead electrode 1, and the constituent component of the case electrode has the three-layered structure of copper-iron alloy-copper, and the iron alloy is formed in such a way as to have the composition of a 30% to 50% with Ni remainder Fe or a 20% to 40% Ni-50% to 60% with Fe remainder Co. The iron alloy having the three-layered structure of the copper-iron alloy-copper has a thickness which is 1.5 to 8 times as large as that of each of the copper layers on both sides. In the above-mentioned semiconductor device, the constituent component of the case electrode has the layer structure of copper-iron alloy-copper. In addition, it is preferable that the iron alloy has the composition of the 30% to 50% with Ni remainder Fe or the 20% to 40% Ni-50% to 60% with Fe remainder Co. In addition, the iron alloy of the three-layered structure of copper-iron alloy-copper has the thickness which is 1.5 to 8 times as large as that of each of the copper layers on the both sides.

For example, in the case where the iron alloy of copper-iron alloy-copper is invar and the thickness ratio of copper-iron alloy-copper is 1:3:1, the coefficient of linear expansion of the case electrode is 6.9 ppm/° C., while in the case where the iron alloy is covar and the thickness ratio thereof is 1:3:1, the coefficient of linear expansion of the case electrode is 6.0 ppm/° C. This means that the three-layered structure of copper-iron alloy-copper having both of the low thermal expansion characteristics and the high heat conduction characteristics is employed as the material for the case electrode, whereby it is possible to reduce the deformation of the semiconductor chip due to the difference in coefficient of linear expansion between the semiconductor chip and the case electrode. In addition, it is possible to reduce the strain which is generated in the adhesive member such as solder. By the way, this layer structure can be formed by pressing the materials with compression bonding.

FIG. 4 is a vertical cross sectional view showing the structure of a semiconductor device according to a fifth embodiment of the present invention.

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through connection members 3a, 3b, 3c, and also including an insulating member 6, an electrically conductive plate 4 is provided between the semiconductor chip 2 and the lead electrode 1, and the electrically conductive plate 4 has the three-layered structure of copper-iron alloy-copper, and the iron alloy has the composition of the 30% to 50% with Ni remainder Fe or the 20% to 40% Ni-50% to 60% with Fe remainder Co. For example, in the case where a thickness (T) of the electrically conductive plate 4 is 500 μm, and the iron alloy of copper-iron alloy-copper is invar, and the thickness ratio thereof is 1:3:1, the coefficient of linear expansion of the case electrode 5 is 6.9 ppm/° C., while the iron alloy is covar and the thickness ratio thereof is 1:3:1, the coefficient of linear expansion of the case electrode is 6.0 ppm/° C.

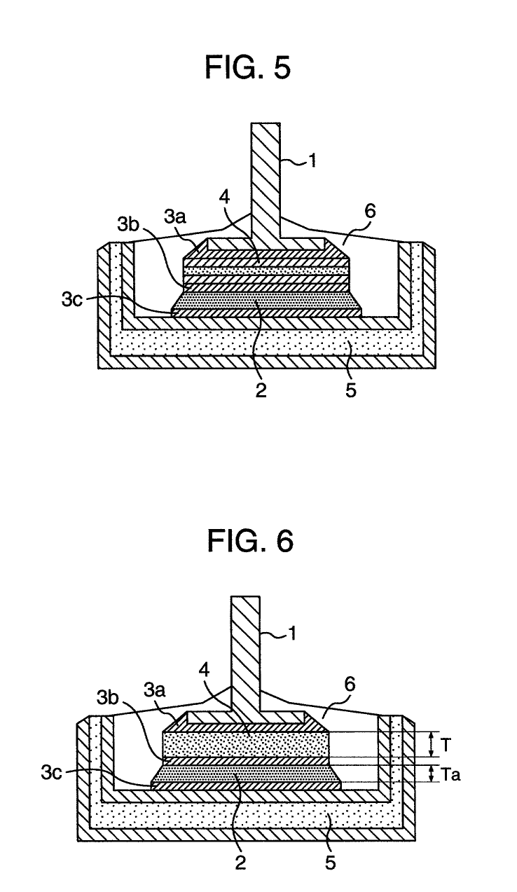

FIG. 5 is a vertical cross sectional view showing the structure of a semiconductor device according to a sixth embodiment of the present invention.

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through connection members 3a, 3b, 3c, and also including an insulating member 6, an electrically conductive plate 4 is provided between the semiconductor chip 2 and the lead electrode 1, and each of the case electrode 5 and the electrically conductive plate 4 has the three-layered structure of copper-iron alloy-copper, and the iron alloy has the composition of the 30% to 50% with Ni remainder Fe or the 20% to 40% Ni-50% to 60% with Fe remainder Co.

FIG. 6 is a vertical cross sectional view showing the structure of a semiconductor device according to a seventh embodiment of the present invention.

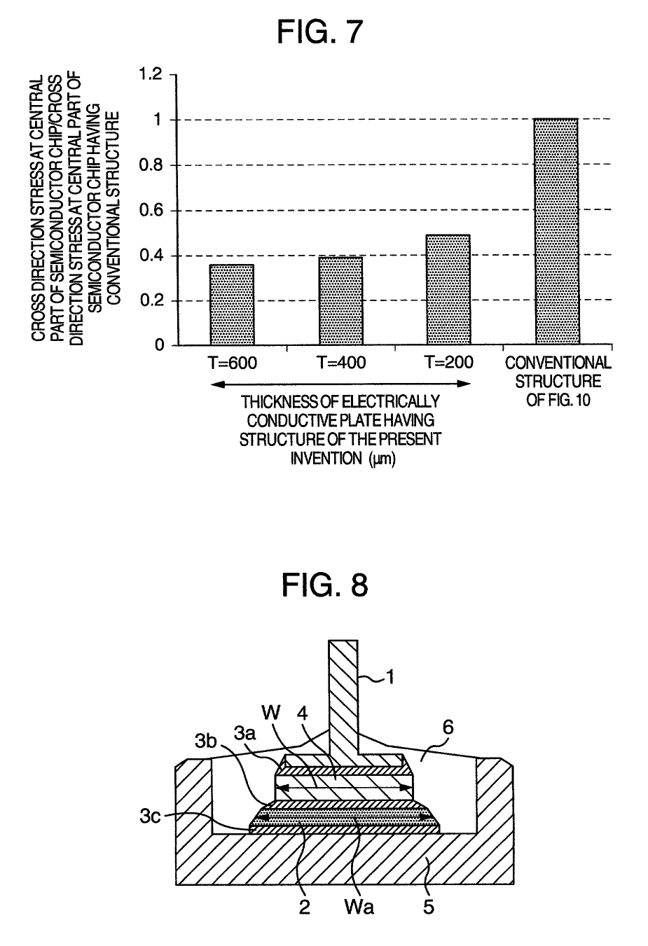

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through connection members 3a, 3b, 3c, and also including an insulating part 6, an electrically conductive plate 4 is provided between the semiconductor chip 2 and the lead electrode 1, and the electrically conductive plate 4 is an electrically conductive plate made of invar (alloy of 35% Ni—Fe) and has a thickness equal to or larger than 50% of that (Ta) of the semiconductor chip 2. The efficient of linear expansion of invar is 1.5 ppm/° C., whereas the coefficient of linear expansion of the semiconductor chip 2 is 3 ppm/° C. which is larger than that of invar. In order to reduce the difference in thermal expansion between invar and the semiconductor chip, the thickness of invar is made larger than that (T) of the semiconductor chip. In addition, since the thickness (T) of the electrically conductive plate is increased, whereby the function of reducing the deformation of the semiconductor chip is also enhanced, it can be expected to reduce greatly the stress exerted to the semiconductor chip 2. FIG. 7 is a graphical representation showing the relationship between the change in thickness (W) of the electrically conductive plate 4 and the ratio of the cross direction stress at the center part of the semiconductor chip 2 to the cross direction stress at the center part of the conventional semiconductor chip 2 for comparison shown in FIG. 10.

A semiconductor device according to an eighth embodiment of the present invention is such that in the semiconductor embodiment shown in FIG. 6, the electrically conductive plate 4 is an electrically conductive plate in which Mo is the main constituent element, and has a thickness equal to or smaller than 200% of that (Ta) of the semiconductor chip. This means that since the coefficient of linear expansion of molybdenum is 5.1 ppm/° C., the thermal deformation of the electrically conductive plate is larger than that of the semiconductor chip 2. In order to reduce the difference in thermal expansion between the semiconductor chip 2 and the electrically conductive plate 4 on the basis of the same function as that of the seventh embodiment, the thickness of the electrically conductive plate 4 is made smaller than that (Ta) of the semiconductor chip.

A semiconductor device according to a ninth embodiment of the present invention is such that in the seventh embodiment of the present invention shown in FIG. 6, the electrically conductive plate 4 is an electrically conductive plate in which W is the main constituent element, and has a thickness equal to or smaller than 200% of that (Ta) of the semiconductor chip. This means that since the coefficient of linear expansion of tungsten is 4.5 ppm/° C., the thermal deformation of the electrically conductive plate 4 is larger than that of the semiconductor chip 2. In order to reduce the difference in thermal expansion between the semiconductor chip 2 and the electrically conductive plate 4 on the basis of the same function as that of the seventh embodiment, the thickness of the electrically conductive plate 4 is made smaller than that (Ta) of the semiconductor chip.

FIG. 8 shows the structure of a semiconductor device according to a tenth embodiment of the present invention.

In the figure, in the encapsulation structure having a lead electrode 1 connected to a lead, a case electrode 5 having a projection part around its periphery, and a semiconductor chip 2 having a rectification function and connected electrically between the lead 1 and the case electrode 5 through connection members 3a, 3b, 3c, and also including an insulating member 6, an electrically conductive plate 4 is provided between the semiconductor chip 2 and the lead electrode 1, and a width (W) of the electrically conductive plate 4 is made smaller than that (Wa) of the semiconductor chip. For example, the electrically conductive plate 4 is formed in such a way that its width (W) is equal to or smaller than 90%, but equal to or larger than 50% of the width (Wa) of the semiconductor chip. The electrically conductive plate may have either a round shape or a polygonal shape.

Since the semiconductor chip and the electrically conductive plate are joined to each other in such a way that the periphery of the electrically conductive plate is located in the inside of the periphery of the semiconductor chip, it is possible to reduce the strain generated in solder between the electrically conductive plate and the semiconductor chip due to the difference in coefficient of linear expansion between the electrically conductive plate and the semiconductor chip. In addition, the electrically conductive plate is arranged on the central side with respect to the end part of the semiconductor chip, whereby it is possible to absorb the concentrated stress which is generated in the end part of the semiconductor chip. Now, according to the result of the numerical calculation, the stress can be absorbed from 10 up to 25 in terms of the predetermined cooling relative value.

In such a manner, there is reduced the generation of any of cracks due to the thermal fatigue caused by the mutual thermal deformation difference between the electrically conductive material and the semiconductor chip which are electrically joined to each other through the joining member. In addition, by taking the heat radiating property into consideration, it is possible to obtain the semiconductor device having the highly reliable heat transfer.

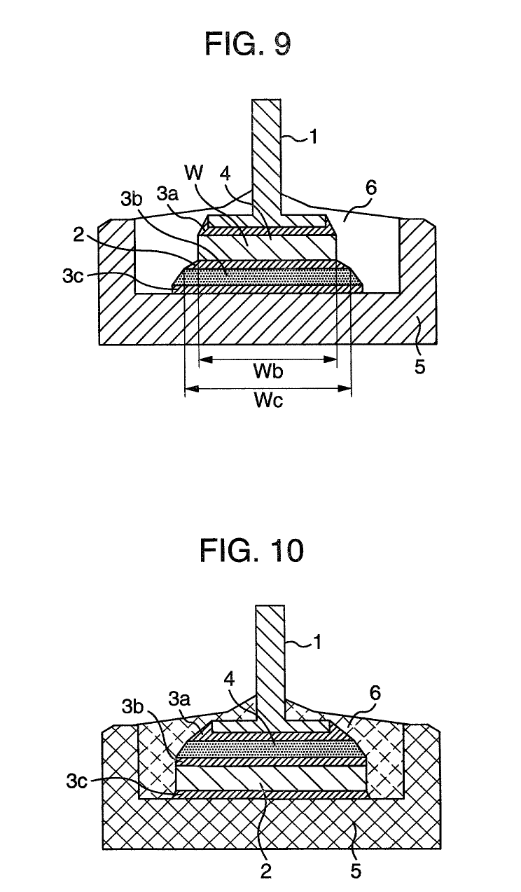

FIG. 9 shows the structure of a semiconductor device according to an eleventh embodiment of the present invention.

In the figure, in the encapsulation structure having a lead electrode 1 connected to a lead, a case electrode 5 having a projection part around its periphery, and a semiconductor chip 2 having a rectification function and connected electrically between the lead electrode 1 and the case electrode 5 through the connection members 3a, 3b 3c, and also including an insulating member 6, an electrically conductive plate 4 is provided between the semiconductor chip 2 and the lead electrode 1, but no electrically conductive plate 4 is provided between the semiconductor chip 2 and the case electrode 5, and each of the lead electrode 1 and the electrically conductive plate 4 is formed in such a way that a width (W) of each of them becomes smaller than that of the semiconductor chip 2, and also a solder as the connection member 3b between the semiconductor chip 2 and the electrically conductive plate 4 is formed in such a way that its width (Wb) of the side end of the electrically conductive plate becomes smaller than its width (Wc) of the side end of the semiconductor chip.

Since the electrically conductive plate and the semiconductor chip are joined to each other in such a way that the periphery of the electrically conductive plate is located in the inside of the periphery of the semiconductor chip, it is possible to reduce the strain which is generated in solder between the electrically conductive plate and the semiconductor chip and in solder between the semiconductor chip and the case electrode due to the difference in coefficient of linear expansion between them two by two. In addition, the electrically conductive plate is located on the central side with respect to the end part of the semiconductor chip, whereby it is possible to absorb the concentrated stress which is generated in the end part of the semiconductor chip.

In such a manner, there is reduced the generation of any of cracks due to the thermal fatigue caused by the mutual thermal deformation difference between the electrically conductive material and the semiconductor chip which are electrically joined to each other through the joining member. In addition, by taking the heat radiating property into consideration, it is possible to obtain the semiconductor device having the highly reliable heat transfer.

It will be further understood by those skilled in the art that the foregoing description has been made on embodiments of the invention and that various changes and modifications may be made in the invention without departing from the spirit of the invention and scope of the appended claims.

What is claimed is:

1. A semiconductor device having a lead electrode connected to a lead, a case electrode having a projection part around its periphery, and a semiconductor chip having a rectification function and connected electrically between said lead electrode and said case electrode through connection members, wherein an electrically conductive plate is provided between said semiconductor chip and said lead electrode.

2. A semiconductor device according to claim 1, wherein the coefficient of linear expansion of said electrically conductive plate is smaller than that of said case electrode and also is equal to or larger than 50% of that of said semiconductor chip.

3. A semiconductor according to claim 1, wherein the strength of said electrically conductive plate is larger than that of said case electrode.

4. A semiconductor device according to claim 1, wherein said case electrode has a layer structure having a metal containing copper through a metal containing iron.

5. A semiconductor device according to claim 1, wherein said electrically conductive plate has a layer structure of copper-iron alloy-copper, and the iron alloy containing a 30% to 50% with Ni remainder Fe or a 20% to 40% Ni-50% to 60% with Fe remainder Co.

6. A semiconductor device according to claim 1, wherein said electrically conductive plate is made of an iron alloy containing a 30% to 50% with Ni remainder Fe or a 20% to 40% Ni-50% to 60% with Fe remainder Co.

7. A semiconductor device according to claim 1, wherein said electrically conductive plate is an electrically conductive plate made of Mo as a main constituent element and having a thickness equal to or larger than 100% of that of said semiconductor chip.

8. A semiconductor device according to claim 1, wherein said electrically conductive plate is an electrically conductive plate made of W as a main constituent element and having a thickness equal to or larger than 100% of that of said semiconductor chip.

9. A semiconductor device having a lead electrode connected to a lead, a case electrode having a projection part around its periphery, and a semiconductor chip having a rectification function and connected electrically between said lead electrode and said case electrode through connection members, wherein an electrically conductive plate is provided between said semiconductor chip and said lead electrode, and a width of said electrically conductive plate is equal to or smaller than 90% and equal to or larger than 50% of that of said semiconductor chip.

10. A semiconductor device having a lead electrode connected to a lead, a case electrode having a projection part around its periphery, and a semiconductor chip having a rectification function and connected electrically between said lead electrode and said case electrode through a solder, wherein an electrically conductive plate is provided between said semiconductor chip and said lead electrode, no electrically conductive plate is provided between said semiconductor chip and said case electrode, and each width of said lead electrode and said electrically conductive plate is smaller than that of said semiconductor chip, and the solder between said semiconductor chip and said electrically conductive plate is formed in such a way that a width of the side end of said semiconductor chip is smaller than that of the side end of said electrically conductive plate.

11. A semiconductor device having a lead electrode connected to a lead, a case electrode having a projection part around its periphery, and a semiconductor chip having a rectification function and connected electrically between said lead electrode and said case electrode through a solder, wherein an electrically conductive plate is provided between said semiconductor chip and said lead terminal, no electrically conductive plate is provided between said semiconductor chip and said case electrode, and each width of said lead electrode and said electrically conductive plate is smaller than that of said semiconductor chip, and the solder between said semiconductor chip and said electrically conductive plate is formed in such a way that a width of the side end of said electrically conductive plate is smaller than that of the side end of said semiconductor chip, and the solder between said semiconductor chip and said case electrode is formed in such a way that a width of the side end of said semiconductor chip is smaller than that of the side end of said case electrode.
